(19) United States
(12) Patent Application Publication
(10) Pub. No.: US 2013/0026565 A1
(43) Pub. Date: Jan. 31, 2013

(54) LOW RDSON RESISTANCE LDMOS

(71) Applicants: Purakh Raj VERMA, Singapore (SG); Guowei ZHANG, Singapore (SG)

(72) Inventors: Purakh Raj VERMA, Singapore (SG); Guowei ZHANG, Singapore (SG)

(73) Assignee: GLOBALFOUNDRIES SINGAPORE PTE. LTD., Singapore (SG)

(21) Appl. No.: 13/189,573

(22) Filed: Jul. 25, 2011

(51) Int. Cl. H01L 29/78; H01L 21/336

(52) U.S. Cl. 257/335; 438/289; 257/E29.255; 257/E21.409

(57) ABSTRACT

A device having a salicide block spacer on a second side of a gate is disclosed. The use of the salicide block spacer indirectly reduces the blocking effects during the implantation processes, thereby lowering the Rdson without compromising the breakdown voltage of the device.

### BACKGROUND

Various voltage level devices may be included in an integrated circuit (IC). For example, low, intermediate and high power devices are provided in an IC. Low power devices may be used for complementary metal oxide semiconductor (CMOS) for logic circuitry, intermediate voltage devices for analog circuitry and high power devices for output high voltage interface stages. It is desirable for high voltage devices to have fast switching speed. The performance of such devices depends on, for example, the on resistance (Rdson) and the drain to source breakdown voltage. The disclosure is directed to a low Rdson while maintaining (or increase) a high breakdown voltage.

### SUMMARY

A low Rdson device and the method of fabricating thereof, are disclosed. In one embodiment, the device comprises a substrate with a device well and a drift well in a device region. The drift well is formed within the device well. The drift well is of first polarity type dopants and the device well is of second polarity type dopants. An internal device isolation region is formed within the drift well. A gate transistor is formed on the substrate in the device region. The gate includes first and second sides. The drift well and internal device isolation region have under-lapping portions beneath the gate. A first diffusion region is formed adjacent to the first side of the gate. A second diffusion region is formed away from the second side of the gate and the internal device isolation region. The first diffusion region is within the device well and the second diffusion region is within the drift well. Both first and second diffusion regions are of first polarity type dopants. A salicide block spacer is disposed on the second side of the gate, adjacent to the drain region. The salicide block spacer defined the active region to be silicided.

In another embodiment, the method of forming the device comprises providing a substrate with a device well and a drift well in a device region. The drift well is formed within the device well. The drift well is of first polarity type dopants and the device well is of second polarity type dopants. An internal device isolation region is formed within the drift well. A gate transistor is formed on the substrate in the device region. The gate includes first and second sides. The drift well and internal device isolation region have under-lapping portions beneath the gate. A first diffusion region is formed adjacent to the first side of the gate. A second diffusion region is formed away from the second side of the gate and the internal device isolation region. The first diffusion region is within the device well and the second diffusion region is within the drift well. Both first and second diffusion regions are of first polarity type dopants. A salicide block spacer is disposed on the second side of the gate, adjacent to the drain region. The salicide block spacer defined the active region to be silicided.

These embodiments, along with other advantages and features herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1a-d show cross-sectional views of various embodiments of a device;

FIGS. 2a-g show cross-sectional views of a process of forming an embodiment of a device; and

FIGS. 3a-b show cross-sectional views of the initial parts of a process of forming another embodiment of a device.

### DETAILED DESCRIPTION

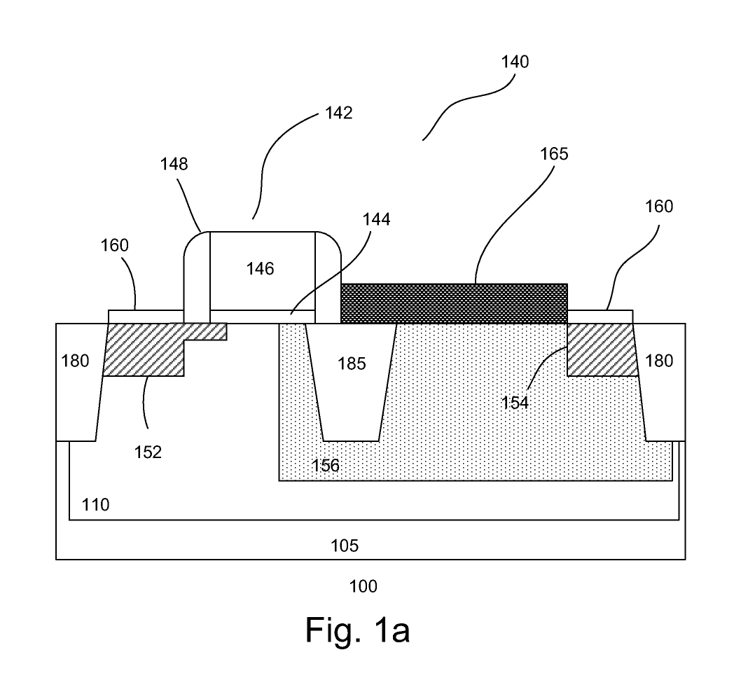

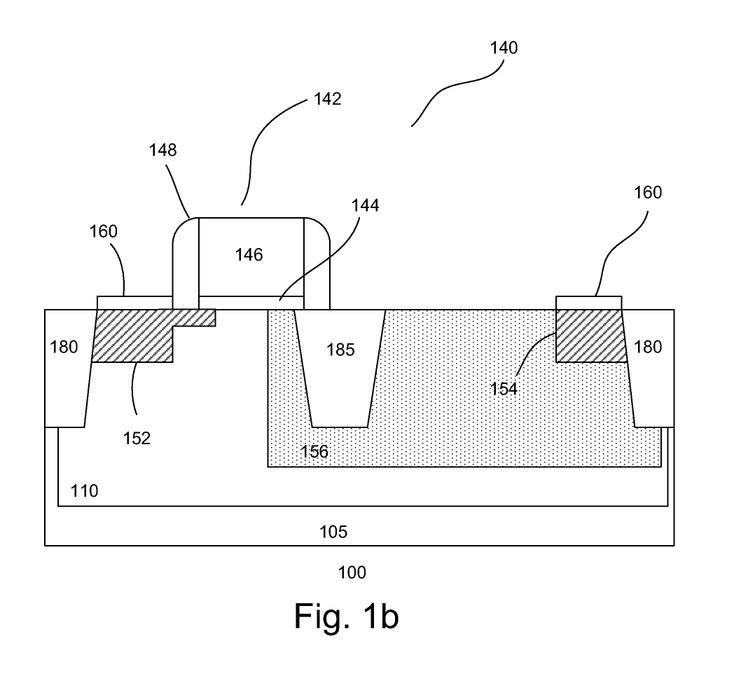

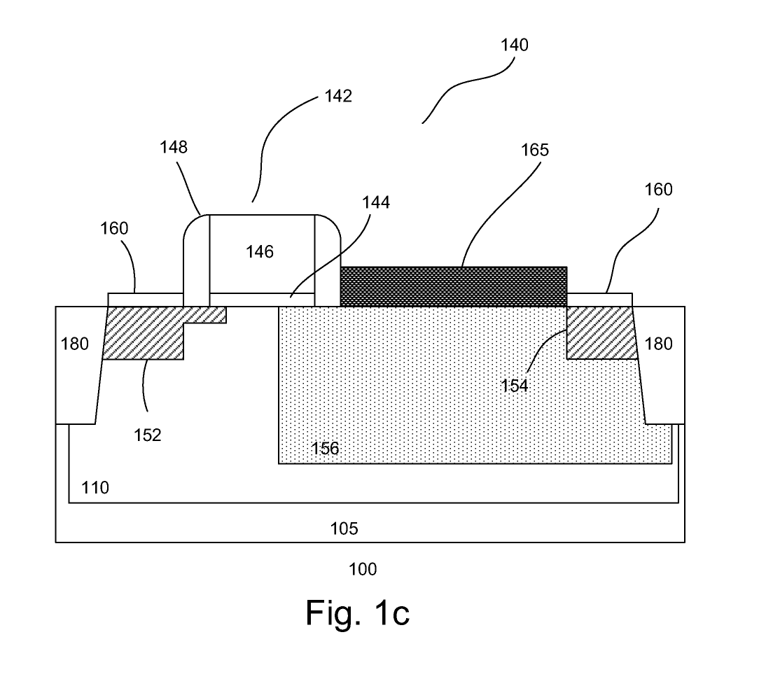

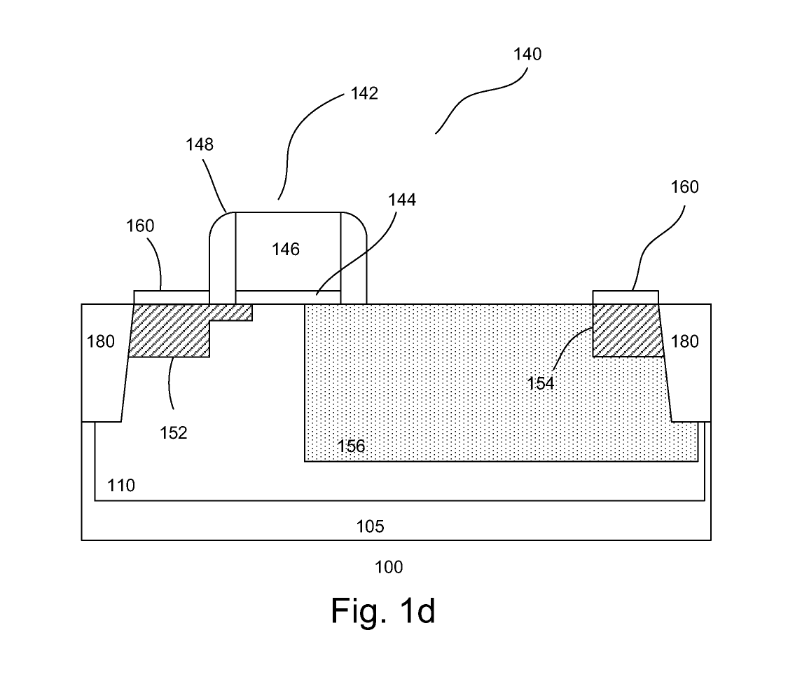

FIG. 1a shows a cross-sectional view of an embodiment of a device 100. The device, as shown, is formed in a device region 110 defined on a substrate 105. The substrate, for example, is a semiconductor substrate, such as a silicon substrate. In one embodiment, the substrate comprises a p-type doped substrate. The p-type doped substrate may be a lightly doped p-type substrate. Other types of semiconductor substrates, including those which are un-doped or doped with the same or other types of other dopants may also be useful. For example, the substrate may be a lightly doped p-type (p⁻) or un-doped silicon layer on a heavily doped p-type (p⁺) bulk or an un-doped or p⁻ silicon on insulator. The substrate may also be other types of substrates.

Isolation regions may be provided for isolating or separating different regions of the substrate. In one embodiment, the device region is isolated from other regions by device isolation regions 180. For example the device isolation region surrounds the device region. An internal device isolation region 185 may also be provided to separate the device region into sub regions. Providing the device isolation regions having other configurations may also be useful. For example, all portions of isolation 180 and 185 may be narrow portions. The isolation regions, for example, are shallow trench isolation (STI) regions. Other types of isolation regions may also be employed. For example, the isolation regions may be deep trench isolation (DTI) regions. The STI regions, for example, extend to a depth of about 2000-5000 Å. In the case of DTI regions, the depth may be about 1-10 μm. Providing STI regions which extend to other depths may also be useful.

A device well is disposed in the substrate. The device well, in one embodiment, defines device region 110. In one embodiment, the device well is disposed within the device isolation regions. For example, the device well is disposed within the device isolation regions, encompassing the source, drain, drift well and internal device isolation, as shown. In one embodiment, the depth or bottom of the device well is below the source, drain and drift well. In one embodiment, the depth or bottom of the device well is below the device isolation regions and internal device isolation region.

The device well comprises second polarity dopants for a first polarity type device. For example, the device well comprises p-type dopants for an n-type device or n-type dopants for a p-type device. The device well may be lightly or intermediately doped with first polarity type dopants. The dopant concentration may depend on, for example, the maximum voltage requirement of the device.

A transistor 140 is provided in the device region. The transistor includes a gate 142 with a first and second side. A first diffusion region 152 and a second diffusion region 154 is disposed in the device region. The first diffusion region may be the source region and the second diffusion region may be the drain region. The source region, for example, may include an extension region and is disposed in the device region adjacent to the first side of the gate. For example, the source region is disposed in the device region adjacent to the first side of the gate and device isolation region. The drain region is disposed in the device region away spaced apart from the second side of the gate. For example, the drain region is disposed in the device region adjacent to the device isolation and the salicide block spacer 165. In one embodiment, the gate is disposed in the device region with the second side of the gate overlapping a portion of the internal device isolation region.

A drift well 156 is disposed in the substrate. The drift well, in one embodiment, is disposed in the device region. For example, the drift well is disposed between the gate and the drain region, under-lapping a portion of the gate. As shown, the drift well encompasses the drain and the internal device isolation region. In one embodiment, the depth or bottom of the drift well is below the drain region. In one embodiment, the depth or bottom of the drift well is below the device isolation and internal device isolation regions. In one embodiment, the drift well is contiguous and encompasses the drain region and at least overlaps a portion of the active region underneath the gate.

The drift well comprises first polarity type dopants for a first polarity type device. For example, the drift well comprises n-type dopants for an n-type device or p-type dopants for a p-type device. The drift well serves as a drift region of the device. The drift well may be lightly or intermediately doped with first polarity type dopants. The dopant concentration may depend on, for example, the maximum voltage requirement of the device.

The gate includes, for example, a gate electrode 146 over a gate dielectric 144. The gate dielectric may comprise silicon oxide. Alternatively, the gate dielectric may comprise silicon oxy-nitride. Other types of gate dielectric materials, such as a high k dielectric material or a composite gate dielectric having a combination of various dielectric materials such as silicon oxide, silicon nitride, other types of dielectric materials or a combination thereof, may be useful. The gate dielectric may be about 60-1000 Å thick, depending on the operating voltage at the gate. Other thickness or other types of gate dielectrics may also be useful. As for the gate electrode, it may comprise of polysilicon. Other types of gate electrode materials, such as different types of metallic materials, may also be useful.

In one embodiment, the source and drain region have n-type dopants for an n-type device. Alternatively, the source and drain region have p-type dopants for a p-type device. The source and drain regions may be heavily doped regions. The depth of the source and drain regions may be about 0.01 to 0.04 μm. Providing source and drain regions having other depths may also be useful. Additionally, it is not necessary that the source and drain regions have the same depth. The source region serves as the source terminal of the transistor; the drain region serves as a drain terminal of the transistor.

The device may include doped regions having different dopant concentrations. For example, the device may include heavily doped (x⁺), intermediately doped (x) and lightly doped (x⁻) regions, where x is the polarity type which can be p or n. A lightly doped region may have a dopant concentration of about 1E11-1E13/cm², and intermediately doped region may have a dopant concentration of about 1E13 to E14/cm², and a heavily doped region may have a dopant concentration of about 1E15-1E17/cm². Providing other dopant concentrations for the different doped regions may also be useful. P-type dopants may include boron (B), aluminum (Al), indium (In) or a combination thereof, while an n-type dopants may include phosphorous (P), arsenic (As), antimony (Sb) or a combination thereof.

For a first polarity type of device, the device well is of a second polarity type and the diffusion and drift regions are of a first polarity type. In the case of n-type devices, the first polarity type is n-type and the second polarity type is p-type. As for a p-type device, the first polarity type is p-type and the second polarity type is n-type.

In one embodiment, dielectric sidewall spacers 148 are provided on sidewalls of the gate. The dielectric sidewall spacers can be, for example, silicon oxide or silicon nitride. Other types of dielectric materials may also be useful. The dielectric spacers may also be a plurality of dielectric layers to form, for example, a composite spacer or spacer stack. Other configurations of spacer may also be useful. The sidewall spacers may be employed to define the source region. Additionally, the sidewall spacers may prevent shorting of the source and drain regions to the gate electrode by the salicidation process used to form the salicide contacts.

In one embodiment, a salicide block spacer 165 is provided on a surface of the substrate, disposed between the drain region and the dielectric sidewall spacer on the opposite side of the source region. The salicide block spacer comprises of a block material to prevent the silicidation of the active surface underneath. In one embodiment, the block material is a dielectric material. For example, the dielectric material may be oxide, nitride, oxynitride or a combination thereof. Other types of dielectric materials may also be useful, for example, such as those compatible for semiconductor processing, for salicide block spacer. The salicide block spacer may also be a plurality of dielectric layers to form, for example, a dielectric stack or sandwich. Other configurations of spacer may also be useful. The salicide block spacer provides a separation between the gate and the drain. The separation distance, in one embodiment, has a direct relationship with the maximum operating voltage and should be sufficient to accommodate the maximum operating voltage at the drain terminal. For example, the separation distance may depend upon the maximum operating voltage at drain terminal. The separation distance may be about 1-2 μm, for an operating voltage of about 30 V at the drain. Providing other separation distances may also be useful. The salicide block spacer prevents silicidation of the drift region between gate electrode and the drain. The salicide block spacer may be about 200-800 Å thick. Other thickness of salicide block spacer may also be useful.

Salicide contacts 160 are formed on the surface of the active region not covered by the salicide block spacer. The salicide contacts are a self-aligned silicided layer. For example, the silicded contacts are self-aligned to the source and drain regions as defined by the dielectric sidewalls, salicide block spacer and device isolation regions. The salicide contacts can be, for example, cobalt silicide (CoSi) or nickel silicide (NiSi). Other types of metal silicidation may also be useful. The salicide contacts may be about 100-500 Å thick. Other thickness of salicide contacts may also be useful. The salicide contacts may be employed to facilitate contact between active regions and the back-end-of-line metal interconnects.

The Rdson of the device is mainly determined by the diffusion path in the drift region, between the drain region and the channel underneath the gate. The internal device isolation acts as a blocking layer during the doping of the drift region, thereby the drift region underneath the isolation has a lower dopant concentration. This increases the Rdson. By providing salicide block spacer, it allows for a narrower internal device isolation region and at the same time, maintaining the desired separation distance between the drain and the gate. A narrower internal device isolation minimizes the blocking effect, creating a more balanced dopant profile along the diffusion path and lowers the Rdson.

FIG. 1b shows a cross-sectional view of another embodiment of a device 100. The device is similar to that described in FIG. 1a. In one embodiment, the salicide block spacer is removed after the salicide contacts were formed. The salicide block spacer prevents silicidation of the drift region between gate electrode and the drain. This unsilicided drift region ensured a separation between the drain region and the gate, supporting a maximum operating voltage at the drain terminal. The lower Rdson of the device due to a more balanced dopant profile along diffusion path is also achieved.

FIG. 1c shows a cross-sectional view of another embodiment of a device 100. The device is similar to that described in FIG. 1a. In one embodiment, the device is without the internal device isolation region to separate the device region into sub-regions. The absence of the internal device isolation eliminates blocking effects of the implantation on the drift region, thereby increasing the dopant concentration and lowers the Rdson. A salicide block is provided on the surface of the drift region between the gate and the drain region. The salicide block spacer prevents silicidation of the drift region between gate electrode and the drain region, providing a separation in between sufficient to accommodate the maximum operating voltage at the drain terminal.

FIG. 1d shows a cross-sectional view of another embodiment of a device 100. The device is similar to that described in FIG. 1a. In one embodiment, the device is without the internal device isolation region to separate the device region into sub-regions. The absence of the internal device isolation eliminates blocking effects of the implantation on the drift region, thereby increasing the dopant concentration and lowers the Rdson. Salicide block spacer is provided on the surface of the drift region between the gate and the drain region, preventing the silicidation of the drift region between gate electrode and the drain region. After the salicide contacts are formed on the surface of the active region, the salicide block spacer is removed. The unsilicided drift region between the gate and the drain region provides a separation in between to accommodate the maximum operating voltage at the drain terminal.

The semiconductor structures of the above embodiments may be further processed using standard fabrication techniques to form the device. For example, an inter-level dielectric layer, contacts, inter-metal dielectric layers and interconnects can be formed.

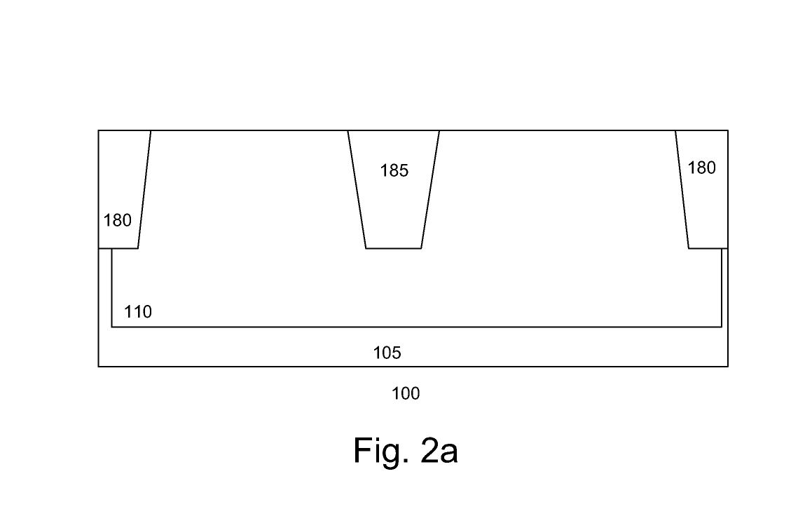

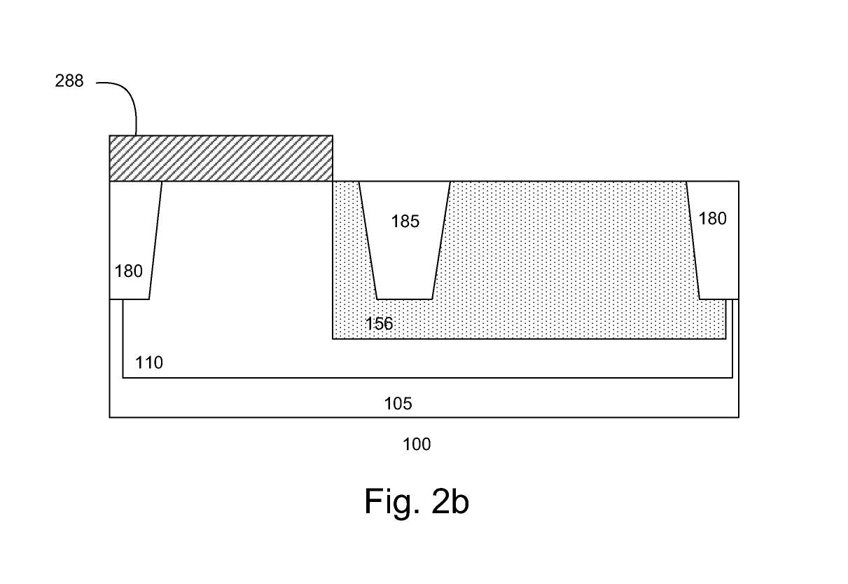

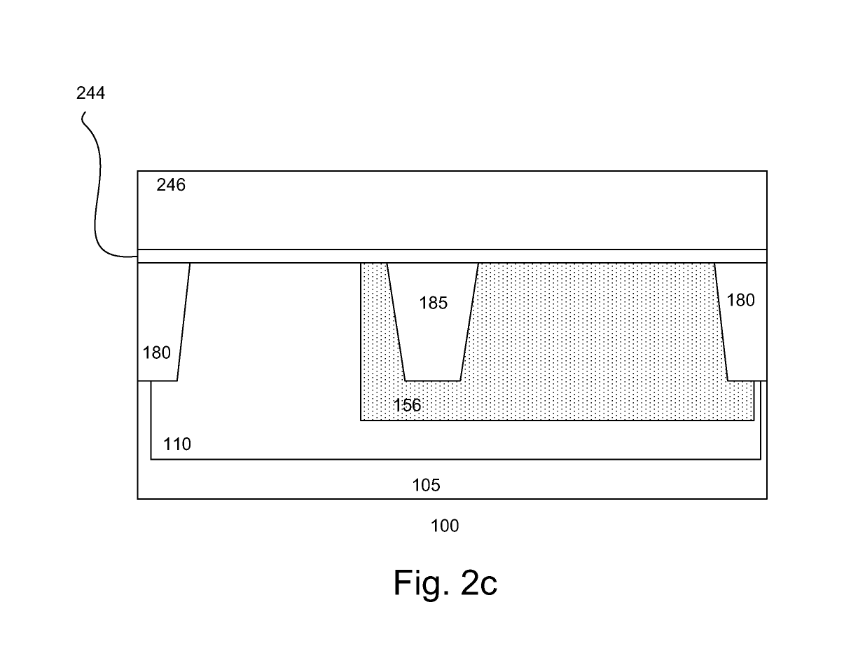

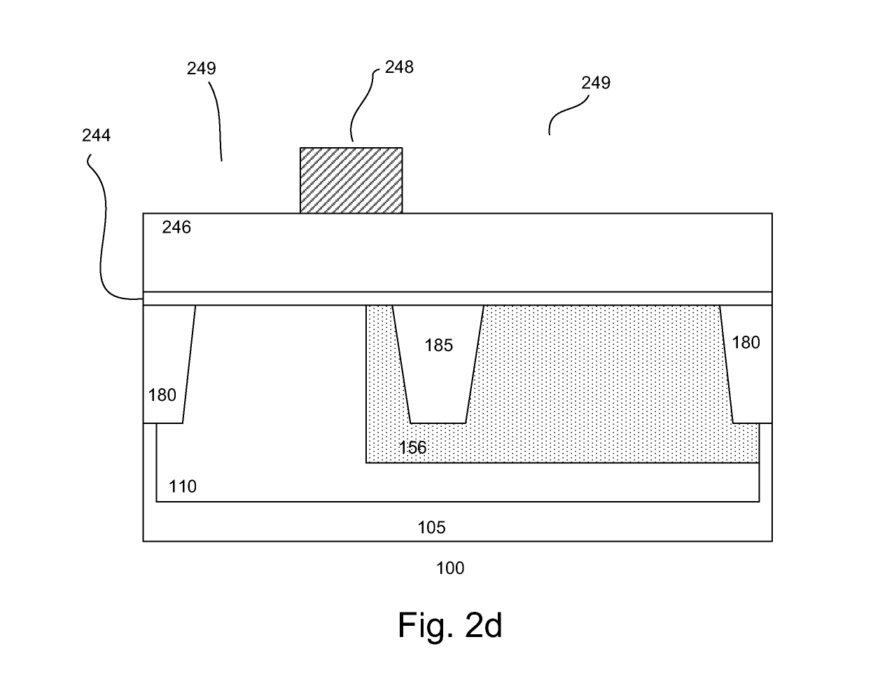

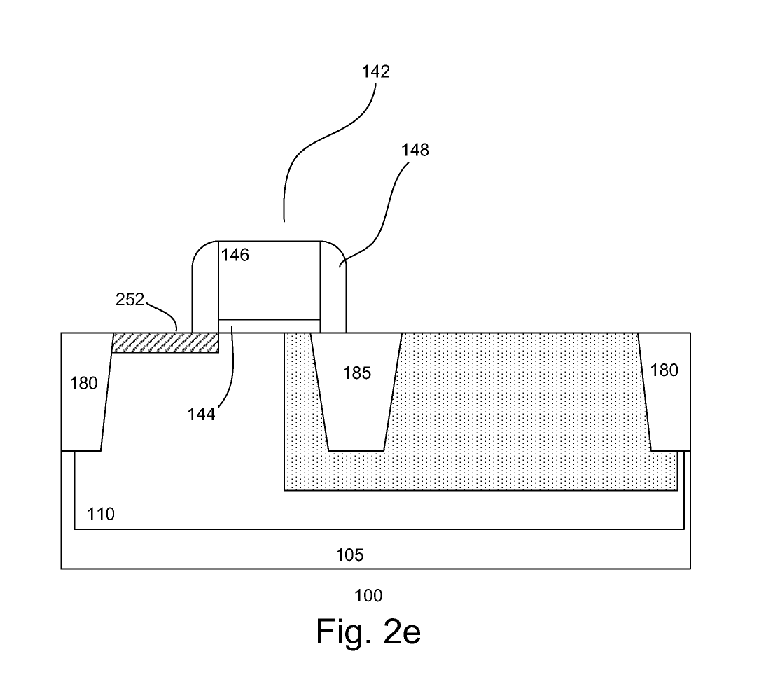

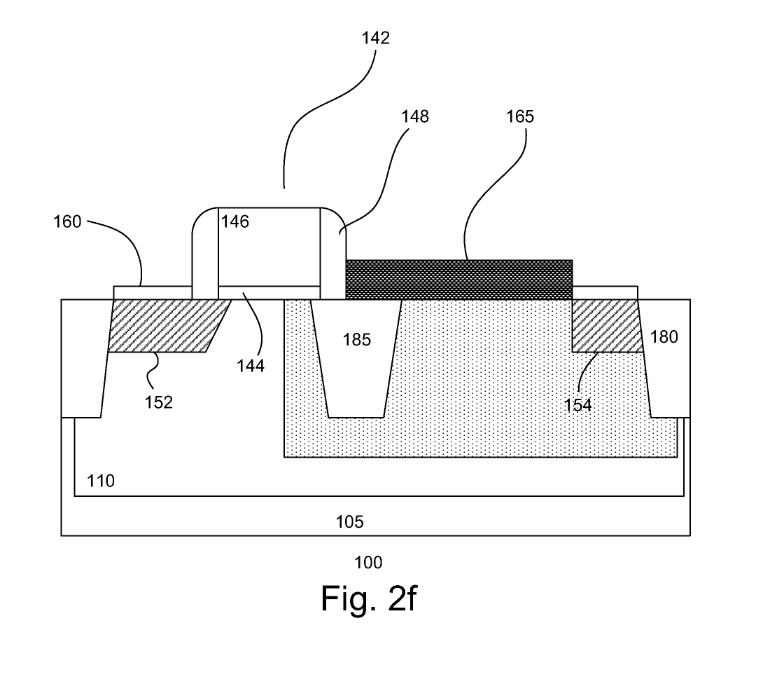

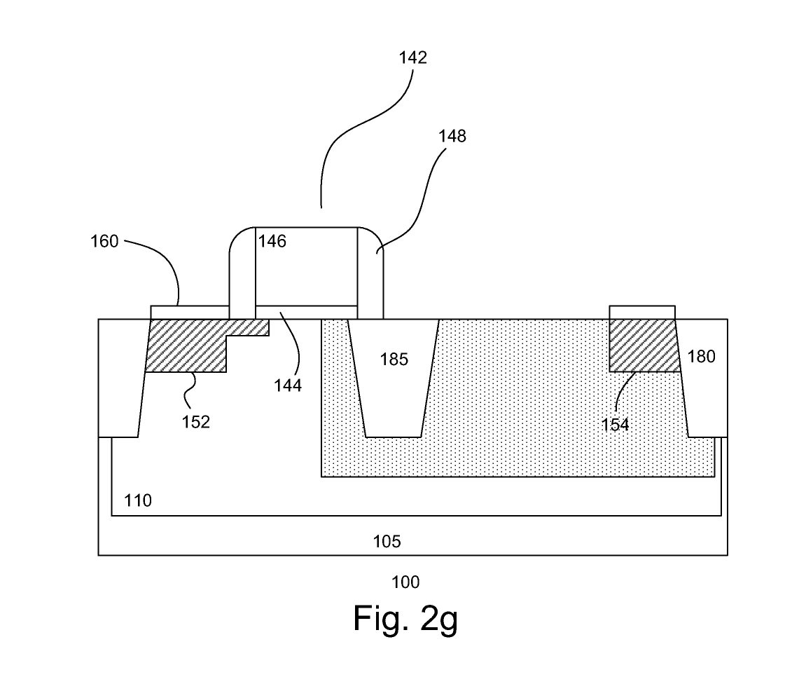

FIGS. 2a-g show cross-sectional views of an embodiment of a process for forming a device or IC. Referring to FIG. 2a, a substrate 105 is provided. The substrate can comprise of a silicon substrate, such as a lightly doped p-type doped substrate. Other types of substrates, including silicon germanium or silicon-on-insulator (SOI) are also useful.

As shown in FIG. 2a, a device isolation region 180 is formed on the substrate. In one embodiment, for example, an internal device isolation region 185 is also formed on the substrate. The isolation regions comprise, for example STIs. Various processes can be employed to form the STI regions. For example, the substrate can be etched using etch and mask techniques to form trenches which are then filled with dielectric materials such as silicon oxide. Chemical Mechanical Polishing (CMP) can be performed to remove excess oxide and provide a planar substrate top surface. Other processes or materials can also be used to form the STIs. In other embodiments, the isolation may be other types of isolation regions. The depth of the STIs may be, for example, about 2000-5000 Å. Other depths of STIs may also be useful. For example, the isolation regions may be Deep Trench Isolation (DTI) regions.

The device isolation region surrounds the device region. In one embodiment, for example, the device region includes the internal device isolation region to separate the device region into sub-regions. Although one device region is shown, it is understood that the substrate may include various types of regions (not shown). For example, the substrate may include other device regions for other types of devices. The IC may include logic regions in which logic devices are formed. Depending on the type of IC formed, the logic regions, for example, may include regions for high voltage (HV) devices, medium or intermediate (IV) devices and low voltage (LV) devices. Other configurations of logic regions may also be useful. Additionally, other types of device regions may also be provided.

A device well 110 is formed on the substrate. The device well, in one embodiment, comprises of the second polarity type and is disposed within the device isolation region. The depth of the device well, for example, may be about 2-10 μm range. Such a depth is useful for a device with a desired operating voltage from about 10-60 V. Providing a device well having other depths may also be useful and, for example, may depend on the desired operating voltage of the device. The device well may be formed by implanting appropriate dopants with the desired dose and power into the substrate. The dopant type, dose and power may depend on the type of device to be formed.

In one embodiment, the device well comprises a p-well for an n-type device. Forming an n-type device well for a p-type device may also be useful. The doped well may be formed by performing multiple implants at different energies. To form the device well, a device well implant mask which exposes the device region is used. The implant mask, for example, comprises photoresist patterned by a lithographic mask. The implant mask may be removed after forming the device well. Other techniques for forming the device well may also may useful.

An anneal may be performed. The anneal diffuses the second type dopants, forming a device well which extends to under the bottom of the internal device isolation region. The anneal, for example, is performed at a temperature of about 1100-1150° C. for about 2-10 hours. Alternatively, the anneal may be a rapid thermal anneal (RTA). Other annealing parameters or processes may also be useful.

In FIG. 2b, a drift well 156 is also formed within the device region. The drift well, in one embodiment, comprises dopants of the first polarity type. In one embodiment, the drift well is formed within the device well. In one embodiment, the depth or bottom of the drift well is below the subsequently formed drain and source regions. In one embodiment, the depth of the drift well is below a bottom of the STI regions. Providing a drift well having other depths may also be useful. The drift well may be formed by implanting appropriate dopants with the desired dose and power into the substrate. The dopant type, dose and power may depend on the type of device to be formed.

In one embodiment, the drift well comprises an n-well for an n-type device. Forming a p-type drift well for a p-type device may also be useful. To form the drift well, a drift well implant mask 288 which exposes the drift region is used. The implant mask, for example, comprises photoresist patterned by a lithographic mask. The implant mask may be removed after forming the drift well. Other techniques for forming the drift well may also useful.

In FIG. 2c, gate layers are formed on the substrate. In one embodiment, a gate dielectric layer 244 is formed on the surface of the substrate. The gate dielectric layer, for example, comprises silicon oxide. Other types of dielectric materials may also be useful. The thickness of the gate dielectric layer may be about 60-1000 Å. For example, the thickness of the gate dielectric layer may be about 100 Å for Vgs of about 5 V and increase to 500 Å for Vgs of about 20 V. Other gate dielectric layer thickness may also be useful. The gate dielectric layer may be formed by thermal oxidation. For example, the dielectric layer is formed by wet oxidation followed by annealing the substrate in an oxidizing ambient. The temperature of the wet oxidation can be, for example, about 600-1000° C. The annealing can be, for example, performed at a temperature of about 1000° C. Other types of gate dielectric materials or thicknesses may also be useful. For example, the gate dielectric material may comprise other types of gate dielectric materials and/or be formed by other types of processes, such as chemical vapor deposition (CVD).

A gate electrode layer 246 is formed on the substrate over the gate dielectric layer. The gate electrode comprises, in one embodiment, polysilicon. The gate electrode layer can be formed as an amorphous or non-amorphous layer. The gate electrode may be doped. Various techniques may be employed to dope the gate electrode, for example, in-situ doping or ion implantation. Other types of gate electrode materials may also be useful. For example, a metallic material may be used to form a metal gate electrode. The thickness of the gate electrode may be about 1000-3000 Å. Other thickness may also be useful. To form the gate electrode layer, techniques such as CVD, can be used. Other techniques may also be useful.

In FIG. 2d, the gate layers are to be patterned to form the gate stack. Techniques, such as mask and etch processes, can be used. In one embodiment, a photoresist layer 248 is formed over the gate electrode layer and patterned, exposing portions of the gate electrode layer 249.

In FIG. 2e, the gate layers are patterned to form gate 142. A gate includes gate electrode 146 over a gate dielectric layer 144. An anisotropic etch, such as reactive-ion-etch (RIE), is performed to remove the exposed portions of the gate electrode layer 249 and the gate dielectric layer below. To improve lithographic resolution, an anti-reflective coating (ARC) can be provided beneath the masking layer 248. Other techniques for patterning the gate layers may also be useful.

In one embodiment, lightly doped drain (LDD) region 252 is formed on the substrate on the source region of the transistor. In one embodiment, the 252 region is a lightly doped region having a having first polarity type dopants. The depth of the LDD regions, for example, is about 0.05-0.2 μm. A LDD implant mask may be used to implant dopants to form the LDD regions. The LDD implant mask, for example, comprises photoresist. The implant mask may be patterned to expose the source region of the transistor. To improve lithographic resolution, an ARC layer may be provided below the photoresist. The implant, for example, is self-aligned to the gate and isolation region. For example, the implant may be self-aligned to the gate and device isolation regions. This increases the processing window for the patterning process to form the LDD implant mask. The implant dose may be from about 5E12-5E13/cm² and the implant energy may be from 10K eV to 100K eV. Other implant parameters may also be useful.

Sidewall spacers 148 are formed on the sidewalls of the gates. To form the sidewall spacers, a dielectric layer is deposited on the substrate. The dielectric layer, for example, may be silicon oxide. Other types of dielectric material, such as silicon nitride, may also be used. The dielectric layer may be formed by CVD. The dielectric layer may also be formed using other techniques. The thickness of the dielectric layer may be, for example, 300-1000 Å. Other thickness for the dielectric layer may also be useful. The thickness, for example, may depend on the desired width of the spacers. An anisotropic etch, such as RIE, may be performed to remove horizontal portions of the dielectric layer, leaving spacers on the sidewalls of the gate. In some applications, the spacer may be formed from multiple dielectric layers.

In FIG. 2f, a source region 152 and drain region 154 are formed on the substrate. The source and drain regions are heavily doped regions having first polarity type dopants. The depth of the source and drain regions. For example, is about 0.1-0.4 μm. A first S/D implant mask may be used to implant dopants to form the different doped regions. The first S/D implants mask, for example, comprises photoresist. The implant mask may be patterned to expose the source and drain regions of the transistors.

In one embodiment, salicide block spacer 165 is formed on the drain side of the gates, as shown in FIG. 2f. In one embodiment, a salicide block spacer includes an extension portion which provides a separation between a gate and its drain. The separation of the gate from the drain helps to with stand higher operating voltage at the drain. In one embodiment, the separation distance is about 2 μm. Providing other separation distances may also be useful.

To form the salicide block spacer, a dielectric layer is formed on the substrate. The dielectric layer, for example, may be oxide, nitride, oxynitride or a combination thereof. Other types of dielectric materials may also be useful for the salicide block spacer. In one embodiment, the salicide block spacer may comprise of a dielectric layer of spacer oxide or nitride. Other configuration such as multiple dielectric layers to form a dielectric stack or sandwich may also be useful.

Patterning the dielectric layer can be achieved using, for example, mask and etch techniques. For example, a photoresist layer is formed over the dielectric layer and patterned using a lithographic mask, exposing portions of the dielectric layer to be removed. An anisotropic etch, such as RIE, is performed to remove exposed portions of the dielectric layer. The sidewall spacers remain on the sidewalls of the gates. To improve lithographic resolution, an anti-reflective coating (ARC) can be provided beneath the photoresist. Other techniques for patterning the dielectric layer may also be useful.

In one embodiment, salicide contact layers 160 are formed on the surface of the active region exposed by the salicide block spacer. In one embodiment, the salicide contacts are formed on the surface of the source and drain regions. The salicide contacts are to facilitate low resistance contacts between the active substrate and the BEOL metal lines. In one embodiment, the thickness is about 200 Å. Providing other thicknesses may also be useful.

To form the salicide contact layers, a metal layer is deposited on the surface of the substrate. The metal layer, for example, may be Cobalt, Nickel or a combination thereof. The metal layer can be formed by Physical Vapor Deposition (PVD). Other types of metal elements and/or be formed by other types of processes can also be useful.

A first anneal may be performed. The first anneal diffuses the metal dopants into the active substrate, forming a silicided layer. The first anneal, for example, is performed at a temperature of about 300-600° C. for about 10-60 seconds. Excess metal not used in the silicidation of the active surface is removed by, for example, a wet removal process. A second anneal may be performed to enhance the material properties of the silicided layer, for example, lower resistivity. The first and second annealing processes may be a rapid thermal anneal (RTA). Other annealing parameters or processes may also be useful.

FIG. 2g illustrates a second embodiment, whereby the salicide block spacer is removed after the silicidation process. The salicide block spacer is removed, for example, a wet removal process. Other removal processes, for example RIE, may also be useful.

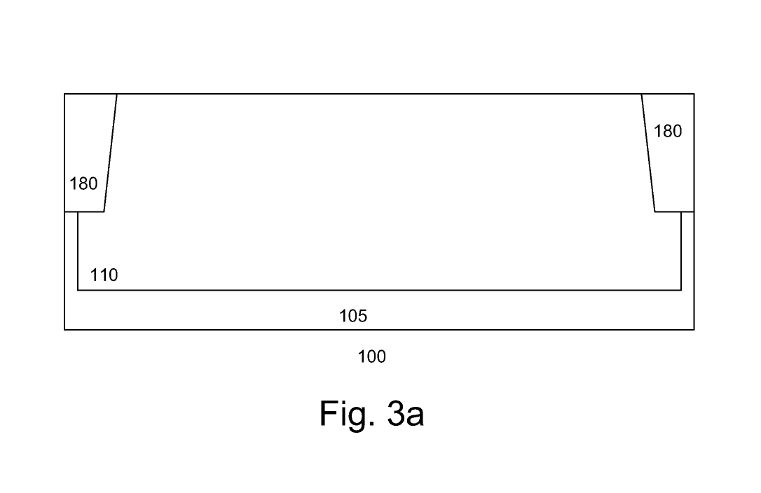

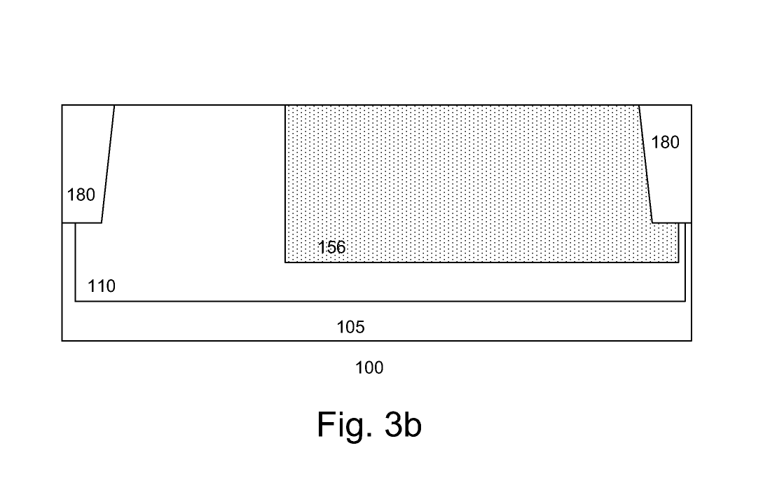

In the third embodiment, a device isolation region 180 is formed on the substrate, as shown in FIG. 3a. In the current embodiment, for example, internal device isolation region 185 is not present on the substrate. The isolation regions comprise, for example STIs. Various processes can be employed to form the STI regions. For example, the substrate can be etched using etch and mask techniques to form trenches which are then filled with dielectric materials such as silicon oxide. Chemical Mechanical Polishing (CMP) can be performed to remove excess oxide and provide a planar substrate top surface. Other processes or materials can also be used to form the STIs. In other embodiments, the isolation may be other types of isolation regions. The depth of the STIs may be, for example, about 2000-5000 Å. Other depths of STIs may also be useful. For example, the isolation regions may be Deep Trench Isolation (DTI) regions.

The device isolation region surrounds the device region. Although one device region is shown, it is understood that the substrate may include various types of regions (not shown). For example, the substrate may include other device regions for other types of devices. The IC may include logic regions in which logic devices are formed. Depending on the type of IC formed, the logic regions, for example, may include regions for high voltage (HV) devices, medium or intermediate (IV) devices and low voltage (LV) devices. Other configurations of logic regions may also be useful. Additionally, other types of device regions may also be provided.

A device well 110 is formed on the substrate. The device well, in one embodiment, comprises of the second polarity type and is disposed within the device isolation region. The depth of the device well, for example, may be about 2-10 μm range. Such a depth is useful for a device with a desired operating voltage from about 10-60 V. Providing a device well having other depths may also be useful and, for example, may depend on the desired operating voltage of the device. The device well may be formed by implanting appropriate dopants with the desired dose and power into the substrate. The dopant type, dose and power may depend on the type of device to be formed.

In the current embodiment, the device well comprises a p-well for an n-type device. Forming an n-type device well for a p-type device may also be useful. The doped well may be formed by performing multiple implants at different energies. To form the device well, a device well implant mask which exposes the device region is used. The implant mask, for example, comprises photoresist patterned by a lithographic mask. The implant mask may be removed after forming the device well. Other techniques for forming the device well may also be useful.

An anneal may be performed. The anneal diffuses the second type dopants, forming a device well which extends to under the bottom of the internal device isolation region. The anneal, for example, is performed at a temperature of about 1100-1150° C. for about 2-10 hours. Alternatively, the anneal may be a rapid thermal anneal (RTA). Other annealing parameters or processes may also be useful.

In FIG. 3b, a drift well 156 is also formed within the device region. The drift well, in the current embodiment, comprises dopants of the first polarity type. In the current embodiment, the drift well is formed within the device well. In the current embodiment, the depth or bottom of the drift well is below the drain and source regions. In one embodiment, the depth of the drift well is below a bottom of the STI regions. Providing a drift well having other depths may also be useful. The drift well may be formed by implanting appropriate dopants with the desired dose and power into the substrate. The dopant type, dose and power may depend on the type of device to be formed.

The subsequent processes for the third embodiment are similar to that described in the first embodiment, with the salicide block spacer as shown in FIG. 1c.

In the fourth embodiment, the processes are similar to that described in the third embodiment, with the salicide block spacer removed as shown in FIG. 1d. The salicide block spacer is removed, for example, a wet removal process. Other removal processes, for example RIE, may also be useful.

Forming the different embodiments involves changing the pattern on the lithographic masks. For example the first and third embodiment, as shown in FIGS. 1a and 1c, there is a internal device isolation region 185 whereby the second and fourth embodiments, as shown in FIGS. 1b and 1d, does not. Additional process steps would also be required. For example, the second and fourth embodiments would require an additional salicide block spacer removal step whereby the first and third embodiments do not. Furthermore, it is understood that the process as described is not limited to the specific sequence of steps disclosed. For example, some steps may be performed in different sequences and/or additional steps may be added.

The embodiments described are highly compatible with current IC fabrication processes. For example, the embodiments described are highly compatible with processes which form HV devices.

The invention may be embodied in other forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

1. A device comprising:
a substrate having an active region;
a gate on the substrate in the active region, the gate includes first and second sides;
a first diffusion region in the substrate in the active region adjacent to the first side of the gate,
a drift well in the substrate in the active region adjacent to the second side of the gate;
a second diffusion region disposed in the drift well, the second diffusion region is separated from the second side of the gate by a separation region containing the drift well; and
salicide contacts over the first and second diffusion regions, wherein the salicide contacts comprises self aligned salicide contacts.

2. The device of claim 1 wherein the second side of the gate overlaps a portion of the drift well.

3. The device of claim 1 wherein:
the active region includes a device well having second polarity type dopants; and
the first, second diffusion region and the drift well comprises first polarity type dopants.

4. The device of claim 3 wherein the first and second diffusion region comprises a higher concentration of dopants than the drift well.

5. The device of claim 1 wherein the gate includes sidewall spacers on the first and second sides of the gate.

6. The device of claim 1 comprises an internal device isolation region within the drift well, the isolation region is separated from the second diffusion region.

7. The device of claim 6 wherein the second side of the gate overlaps the drift well and a portion of the internal device isolation region.

8. The device of claim 6 wherein the drift well comprises a substantially uniform dopant concentration.

9. The device of claim 6 comprises salicide contacts over the first and second diffusion regions.

10. The device of claim 9 comprises a salicide block spacer disposed on the substrate from the second side of the gate to the second diffusion region for the self-aligned salicide contacts.

11. The device of claim 1 comprises a salicide block spacer disposed on the substrate from the second side of the gate to the second diffusion region for the self-aligned salicide contacts.

12. A device comprising:
a substrate having an active region;
a gate on the substrate in the active region, the gate includes first and second sides;
a first diffusion region in the substrate in the active region adjacent to the first side of the gate,
a drift well in the substrate in the active region adjacent to the second side of the gate; and
an internal device isolation region within the drift well, the isolation; and
a second diffusion region disposed in the drift well, the second diffusion region is separated from the isolation region a separation region containing the drift well.

13. A method of forming a device comprising:
providing a substrate defined with an active region;
forming a gate of a transistor on the substrate in the active region, the gate having first and second sides;
forming a first diffusion region in the substrate in the active region adjacent to the first side of the gate;
forming a drift well in the substrate in the active region adjacent to the second side of the gate;
forming a second diffusion region in the drift well, the second diffusion region is separated from the second side of the gate by a separation region containing the drift well; and
forming salicide contacts over the first and second diffusion regions, wherein the salicide contacts comprises self aligned salicide contacts.

14. The method of claim 13 wherein:
forming a device well in the active region having second polarity type dopants; and
the first, second diffusion region and drift well having a first type polarity dopants.

15. The method of claim 14 wherein the first and second diffusion region comprises a higher concentration of dopants than the drift well.

16. The method of claim 13 comprises forming the gate wherein the second side of the gate overlaps a portion of the drift well.

17. The method of claim 13 wherein the gate includes sidewall spacers on the first and second sides of the gate.

18. The method of claim 13 comprises
forming an internal device isolation region within the drift well, the isolation region is separated from the second diffusion region.

19. The method of claim 18 wherein the second side of the gate overlaps the drift well and a portion of the internal device isolation region.

20. The method of claim 18 wherein the drift well comprises a substantially uniform dopant concentration.

21. The method of claim 18 comprises salicide contacts over the first and second diffusion regions.

22. The method of claim 13 comprises a salicide block spacer disposed on the substrate from the second side of the gate to the second diffusion region for the self aligned salicide contacts.
